(19) United States
(12) Patent Application Publication
(10) Pub. No.: US 2002/0170496 A1
(43) Pub. Date: Nov. 21, 2002

(54) Continuous processing apparatus by plasma polymerization with vertical chamber

(75) Inventors: Sam-Chul Ha, Changwon (KR); Young-Man Jeong, Kimhae (KR); Seak-Je Jo, Changwon (KR); Dong-Sik Youn, Changwon (KR)

Correspondence Address: OSTROLENK FABER GERB & SOFFEN, 1180 AVENUE OF THE AMERICAS, NEW YORK, NY, 100368403

(73) Assignee: LG Electronics Inc.

(21) Appl. No.: 09/894,034

(22) Filed: Jun. 28, 2001

(30) Foreign Application Priority Data
May 17, 2001 (KR) 26974/2001

(51) Int. Cl. C23C 16/00

(52) U.S. Cl. 118/718; 118/723 E

(57) ABSTRACT

A continuous processing apparatus by plasma polymerization having a plurality of chambers to perform a surface processing by plasma polymerization on the surface of a substance being moved into a chamber, includes at least one vertical chamber in which a substance is vertically moved and at least one electrode is included therein. Since the vertical chamber can be possibly formed solely or by plural ones, or can be formed along with the horizontal chamber, various forms of plasma polymerization processing system can be constructed. In addition, the plurality of chambers can be utilized for various functions and use such as the polymerization chamber, the post-processing chamber and pre-processing chamber according to purposes of surface processing.

### BACKGROUND OF THE INVENTION

1. Field of the Invention

The present invention relates to a continuous processing apparatus by plasma polymerization with a vertical chamber, and more particularly, to a continuous processing apparatus by plasma polymerization with at least one vertical chamber in which a material to be subject to surface processing is vertically moved

2. Description of the Background Art

When the surface of a substance to be coated such as a metal plate undergoes plasma discharging, a coated layer with an excellent hardness and abrasion resistance is formed thereon. A product with such a coated layer is used as a magnetic disk, an optical disk or a cemented carbide tool.

In addition, when a paint coated film formed on the surface of a steel plate undergoes plasma processing, a hard paint coated steel plate having an excellent durability and corrosion resistance is obtained.

WO 99/28530 (laid open Jun. 10, 1999) discloses a surface processing apparatus by plasma polymerization.

FIG. 1 is a schematic plan view of a plasma polymerizing apparatus in accordance with a conventional art.

As shown in FIG. 1, a conventional plasma polymerizing apparatus includes a vacuum chamber 1, vacuum pumps 5 and 6 controlling a pressure inside the vacuum chamber, measuring instruments 7 and 8 measuring a vacuum degree, a power supply unit 3 generating a potential difference to a substance, and reactive gas controlling units 9 and 10 injecting a polymerizing gas such as an unsaturated hydrocarbon gas such as acetylene and a non-polymerizing gas such as nitrogen around the substance to be surface-processed.

A substance 2 is disposed in the chamber and a rotary pump 6 is initiated. After the pressure inside the chamber is adjusted at 10⁻⁶ Torr, a diffusion pump 5 is initiated to maintain the pressure inside the chamber at 10⁻⁶ Torr.

The substance is biased by the power supply unit, and the opposite electrode 4 is grounded.

When the pressure inside the chamber is maintained at a certain vacuum degree, an unsaturated aliphatic hydrocarbon gas such as acetylene and a non-polymerizing gas such as nitrogen are injected into the chamber.

As the pressure inside the chamber comes to a certain level, plasma discharging occurs with DC or a high frequency.

Then, molecular bonds of gases are cut off in the plasma generated by the DC or the high frequency, and the cut chain and the activated positive ions or negative ions are bonded to form a polymerized substance on the surface of a substrate posed between electrodes.

However, the conventional surface processing apparatus by plasma polymerization has many problems.

For example, first, since it performs the surface processing in such a manner that one substance is surface-processed, a different substance is newly put in the chamber and surface-processed. Thus, it is hard to surface-process continuously a large amount of substances.

Secondly, in case of processing a surface of a substance such as a metal sheet or polymer film by plasma polymerization, as polymerization process proceeds, a polymerized substance is formed at the electrode, causing the electrode to be carbonized, creating carbide. Then, as the carbide is released from the electrode, it falls down to the surface of a substance being surface-processed, damaging the surface.

Thirdly, it is difficult to evenly maintain flowing of the polymerizing gas or nonpolymerizing gas introduced into the chamber to the surface of the substance. Such heterogeneity of the gas flowing causes to have different surface processing effect according to positions of the surface of the substrate, being an obstacle to forming evenly a polymerized film on the surface of the substrate.

Fourthly, in the course of surface-processing in the chamber for a long time period, the substance fails to maintain a certain tensile force, sagging down due to gravity. Also, in such a case, each portion of the surface of the substrate has different surface-processing effect.

### SUMMARY OF THE INVENTION

Therefore, an object of the present invention is to provide a continuous processing apparatus by plasma polymerization that is capable of more effectively obtaining a high quality plasma polymerized film.

Another object of the present invention is to provide a plasma polymerization processing system allowing various forms by successively disposing a plurality of chambers.

Still another object of the present invention is to provide a plasma polymerization processing system that is capable of reducing possibility that carbide created as an electrode is carbonized is falls down onto the surface of a substance.

Yet another object of the present invention is to provide a plasma polymerization processing system that is capable of enabling gas injected into a chamber to flow smoothly and evenly so that the surface-processing effect can be evenly made for each portion of the surface.

Still yet another object of the present invention is to provide a plasma polymerization processing system having a plurality of chambers of which an installation space is considerably reduced.

Another object of the present invention is to provide a plasma polymerization processing system that is capable of preventing a substance to be surface-processed from sagging down due to gravity.

To achieve these and other advantages and in accordance with the purpose of the present invention, as embodied and broadly described herein, there is provided a continuous processing apparatus by plasma polymerization having a plurality of chambers to perform a surface processing by plasma polymerization on the surface of a substance being moved into a chamber, includes: at least one vertical chamber in which a substance to be coated is vertically moved and at least one electrode is included therein.

In the continuous processing apparatus by plasma polymerization of the present invention, the electrode is preferably disposed in parallel to the movement direction of a substance in the vertical chamber.

In the continuous processing apparatus by plasma polymerization of the present invention, in case that the continuous processing apparatus includes a plurality of vertical chambers, preferably, a substance is surface-processed by plasma polymerization in one of the vertical chambers.

In the continuous processing apparatus by plasma polymerization of the present invention, a substance to be surface-processed by being continuously moved to the plurality of chambers can be used in itself as an electrode when power is applied thereto.

In a continuous processing apparatus by plasma polymerization in accordance with one embodiment of the present invention, the vertical chamber includes a chamber body in which a substance is moved vertically, one side thereof being opened, a chamber door combined to the opened side of the chamber body, and at least one electrode disposed in parallel to the movement direction of the substance.

In a continuous processing apparatus by plasma polymerization in accordance with another embodiment of the present invention, the vertical chamber is an integrated vertical chamber in which a partition plate is formed at the center thereof to divide the chamber into two vertical areas.

The continuous processing apparatus by plasma polymerization of the present invention may include at least one horizontal chamber in which a substance is horizontally moved as well as a vertical chamber in which the substance is moved vertically, so that a plurality of chambers can be connected in various form.

Preferably, the continuous processing apparatus by plasma polymerization of the present invention includes an unwinding chamber having an unwinding roll for unwinding a substance wound in a roll state and a winding roll for winding a surface-processed substance, for a continuous surface processing.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic view showing a plasma polymerizing apparatus in accordance with a conventional art;

FIG. 2A is a sectional view showing a continuous processing apparatus by plasma polymerization in accordance with one embodiment of the present invention;

FIG. 2B is an enlarged sectional view showing a vertical chamber of FIG. 2A in accordance with one embodiment of the present invention;

FIG. 2C is a sectional view of another example of a vertical chamber n accordance with a preferred embodiment of the present invention;

FIG. 2D is a sectional view of still another example of a vertical chamber in accordance with the preferred embodiment of the present invention;

FIG. 3A is a sectional view showing one example of supply of gas into the vertical chamber in accordance with the preferred embodiment of the present invention;

FIG. 3B is a sectional view showing another example of supply of gas into the vertical chamber in accordance with the preferred embodiment of the present invention;

FIG. 4 is a sectional view of a horizontal chamber of a continuous processing apparatus by plasma polymerization in accordance with the preferred embodiment of the present invention;

FIG. 5A is a sectional view showing a vertical chamber having two vertical areas in accordance with one embodiment of the present invention,

FIG. 5B is a sectional view showing a vertical chamber having two vertical areas in accordance with another embodiment of the present invention; and

FIG. 6 is a sectional view showing a vertical chamber having two vertical areas in accordance with still another embodiment of the present invention.

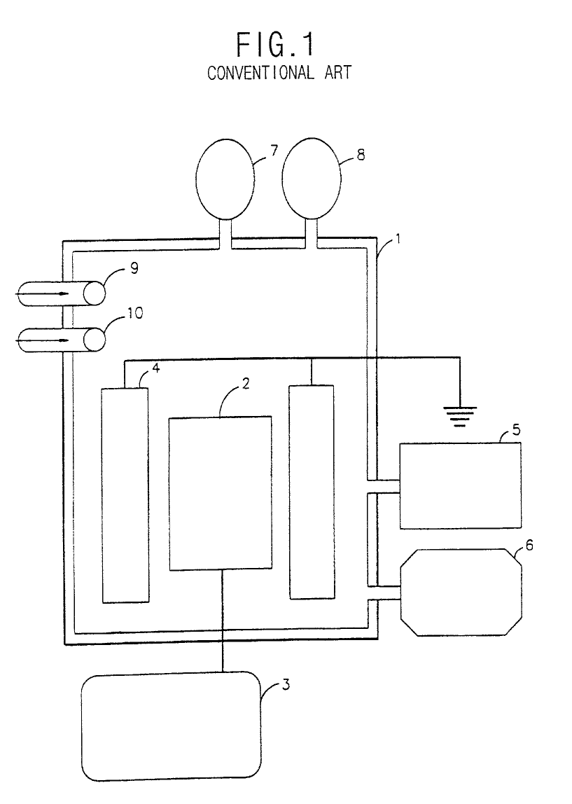

### DETAILED DESCRIPTION OF THE PREFERRED EMBODIMENTS

Reference will now be made in detail to the preferred embodiments of the present invention, examples of which are illustrated in the accompanying drawings.

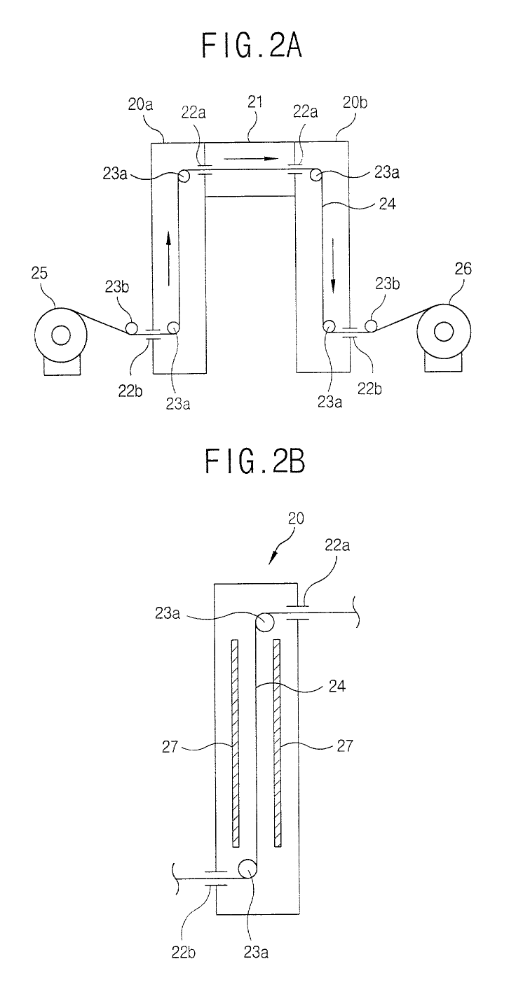

FIG. 2A is a sectional view showing a continuous processing apparatus by plasma polymerization in accordance with one embodiment of the present invention.

As shown in FIG. 2, the a continuous processing apparatus by plasma polymerization of the present invention roughly includes a first vertical chamber 20a, a second vertical chamber 20b, a horizontal chamber 21 disposed between the two vertical chambers 20a and 20b, an unwinding roll 25 for unwinding a substance wound thereon so as to be conveyed to the chamber, and a winding roll 26 for winding the surface-processed substance of a sheet form thereon.

The horizontal chamber may be a horizontal pipe simply used as a convey path of the substance regardless of the surface processing.

The unwinding roll and the winding roll may be installed in separate chambers (i.e., an unwinding chamber and a winding chamber) unlike those as shown in FIG. 2A.

In the preferred embodiment of the present invention, only two vertical chambers are presented, but a third and a fourth vertical chamber may be further included depending on a polymerizing system. Or, various modifications can be made by constructing a polymerizing system with more than four vertical chambers, or with a plurality of horizontal chambers.

The substance conveyed from the unwinding roll passes a thorough hole 22b, advances into the first vertical chamber and is moved vertically, so that the substance undergoes surface processing.

Next, after the substance passes the horizontal chamber 21 through the thorough hole 22a from the first vertical chamber, it is conveyed to the second vertical chamber, in which the substance is subjected to surface processing and then finally wound on the winding roll.

Tension rolls 23a and 23b are disposed on the path where the substance is conveyed between each chamber and between the unwinding roll and the winding roll, to allow a tensile force to the substance and thus prevent the substance from sagging down as well as to change the movement direction of the substance. Accordingly, even though the substance is moved along a continuously long path, a certain movement rate is constantly maintained.

In the preferred embodiment of the present invention, preferably, at least one vertical chamber is installed in the polymerization processing system, and a plurality of vertical chambers and horizontal chambers may be disposed together according to a purpose of surface processing.

Especially, in case that several horizontal chambers and vertical chambers are installed, a gas atmosphere, a pressure and an applied voltage in each chamber are suitably controlled so that surface processing may be performed by different processes by chambers. Also, at least one polymerization condition among a type of gas, a supply ratio of gases, range of voltage applied to an electrode and a pressure inside the chamber is rendered to be the same for a more than two adjacent chambers, so as to be used as a polymerization chamber.

In addition, the surface processing in each chamber may be divided into a pre-processing, a first polymerization processing, a second polymerization processing and a post-processing, so that when a substance passes several chambers, various surface-processing can be made for the substance.

Especially, in a chamber for pre-processing, it is preferred to perform cleaning to remove various contaminants attached on the surface of the substance before the polymerized film is formed by plasma discharging.

Accordingly, the pre-processing chamber is to be positioned ahead the movement path of the substance. Nonpolymerization gas such as oxygen, nitrogen or argon is injected into the pre-processing chamber, so that the surface of the substance is cleaned by plasma discharging.

The polymerizing process, in which the polymerization gas is injected into the chamber and a DC or a high frequency voltage is applied thereto to cause plasma discharging, may be performed in the vertical chamber or in the horizontal chamber. In this respect, in order to solve the problem arisen in the conventional art, at least one vertical chamber is preferably used as a polymerization chamber.

After the substance is surface-processed in the polymerization chamber, it is preferred that surface processing is successively performed by plasma discharging in a different chamber after air is injected thereto. Such post-processing under the air helps to prevent the characteristic of the surface of the substance with polymerized film formed thereon from gradually reducing.

As mentioned above, the plasma polymerization processing apparatus having the plurality of chambers including the vertical chamber can accomplish various surface processing effects of the substance through multi-step processes, and every surface processing required for the substance can be performed by one time once the substance is moved from the unwinding roll to the winding roll.

In the vertical chamber of the preferred embodiment of the present invention, since the substance is moved vertically, that is, upwardly or downwardly, it is preferred that the electrode is also installed vertically inside the chamber.

FIG. 2B is an enlarged sectional view of the vertical chamber of FIG. 2A in accordance with one embodiment of the present invention.

The vertical chamber is formed rectangular parallelepiped of which width-to-height ratio is greater than ‘1’, and the area occupied by the base plane of the chamber is very small compared with the that of the horizontal chamber, so that the overall space of the polymerization processing system is considerably reduced.

An electrode 27 is installed in the chamber, which is disposed vertically to be parallel to the movement direction of the substance 24.

Though it is shown in the drawing that one electrode is installed in both chambers, several electrode may be disposed vertically in a line. Substance through holes 22a and 22b are shown installed at the upper side face and the lower side face of the chamber.

FIG. 2C is a sectional view of another example of a vertical chamber n accordance with a preferred embodiment of the present invention.

As shown in FIG. 2C, a vertical chamber 20 includes a chamber body 29a including an electrode 27 therein and a chamber door 29b attached to one side of the chamber, for opening and closing the chamber. Another electrode 28 is attached on the inner face of the chamber door.

Since the electrode is attached on the chamber door, only one face of the electrode (the opposite face of the substance) participates in the plasma discharging, and generation of carbide on the other face due to the polymerization material is prevented.

In addition, since the electrode is simply attached on the chamber door, installation of the electrode is easy.

Also in this embodiment of the present invention, likewise in the above descriptions, electrodes may be disposed in parallel to the movement direction of the substance.

Meanwhile, unlikely from the case of FIG. 2B, it is noted that the substance through hole 22a is formed at the top and the bottom of the chamber.

As for the vertical chamber, the through hole may be selectively formed at the top and the bottom or at the upper and the lower side faces according to the convey path of the substance and the connection structure between chambers.

Accordingly, even if a plurality of vertical chambers and horizontal chambers are connected to various forms, the movement direction of the substance can be freely changed from vertical direction to the horizontal direction and then from the horizontal direction to the vertical direction.

FIG. 2D is a sectional view of still another example of a vertical chamber in accordance with the preferred embodiment of the present invention.

As shown in FIG. 2D, a vertical chamber is somewhat different from that of FIG. 2C. That is, the electrode 28 installed in a chamber door 29c is separated from the door face. In this structure, it is easy to render the position of the electrode to be near the surface of a substance by controlling the distance between the electrode and the substance.

With reference to FIGS. 2B through 2D, two electrodes facing both surfaces of the substance are installed in the chambers. A DC or an AC voltage may be applied to the electrode, and power may be also applied to the surface-processed substance so that the substance can be used as an electrode.

In order to apply power to the substance, power is applied to the portion contacting the substance so that the power can be indirectly applied to the substance.

For example, rollers are installed in various chambers such as an unwinding chamber having an unwinding roll, a winding chamber having a winding roll and a polymerization chamber, and preferably, power is applied to one of the rollers contacted by the substance being moved, thereby applying the power to the substance. In such a case, a power supply unit is additionally included inside or outside the chamber to apply power to the roller.

As the power is applied to the substance, the substance can be an anode or a cathode. In this respect, it is more preferable in view of a surface processing effect that the substance becomes anode and the facing electrode becomes an opposed electrode facing both faces of the substance.

In surface processing by plasma discharging, gas flowing introduced into the chamber is critical. If gas does not evenly flow in the chamber, homogeneity of surface processing of the substance is degraded.

Especially, in the continuous surface processing, it is very hard to maintain gas flowing evenly for the substance being conveyed. Thus, in case of the vertical chamber of the preferred embodiment of the present invention, since the movement direction of the substance is vertical, compared to the horizontal chamber, the gas supplied into the chamber flows very evenly against the substance.

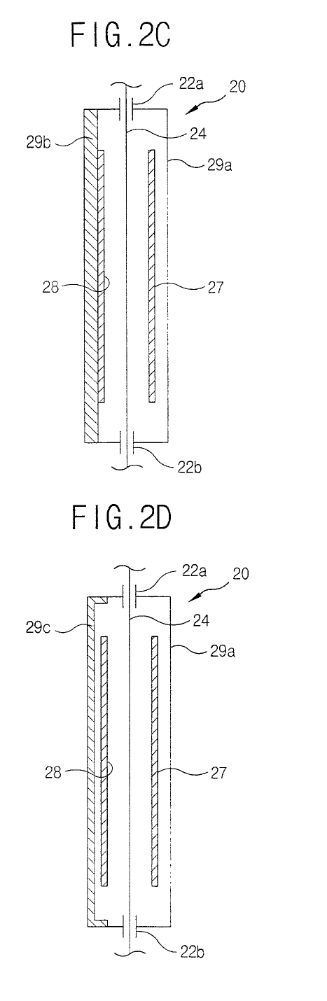

FIG. 3A is a sectional view showing one example of supply of gas into the vertical chamber in accordance with the preferred embodiment of the present invention.

A gas inlet 31a is formed at the bottom of the vertical chamber 20, and a gas outlet 31b is formed at the top thereof.

In such a case, gas flowing is parallel to the movement direction of the substance, so that gas is supplied evenly to each position of the surface of the substance.

In the preferred embodiment of the present invention, gas may flow in the same direction as the movement direction of the substance or in the opposite direction. In case that the substance is to be moved upwardly, the gas inlet is disposed at the upper side of the chamber and the gas output is disposed at the lower side thereof, so that the substance movement direction and the gas flowing can be opposite to each other.

FIG. 3B is a sectional view showing another example of supply of gas into the vertical chamber in accordance with the preferred embodiment of the present invention.

As shown in FIG. 3B, it is noted that the gas is supplied in the horizontal direction to the chamber, unlike the embodiment of FIG. 3. The gas supplied to a gas inlet 32a flows vertically to the substance movement direction and then discharged through a gas output 32b. Though there are shown only two gas inlets and outlets, respectively, in the drawing, more gas inlets and gas outlets may be formed at the right and the left sides of the chamber to make the gas to flow evenly and smoothly.

No matter which direction the gas flows, that is, in parallel or vertically to the substance movement direction in the vertical chamber, the contamination on the surface as carbide generated during polymerizing process clings thereto is remarkably reduced in the vertical chamber of the preferred embodiment of the present invention. The reason for this is that since the substance is moved vertically, a possibility that carbide clings onto the surface of the substance is very low compared to the case where the substance is moved horizontally.

Accordingly, an ash removing unit is not necessary to remove carbide or various dusts attached on the surface of the substance, simplifying the structure of the apparatus.

The plasma polymerizing apparatus as shown in FIG. 2A includes the horizontal chamber as well as the vertical chamber. Like the vertical chamber, the horizontal chamber also can be a polymerization chamber. In the horizontal chamber, the pre-process may be performed before polymerization process or the post-process may be performed after polymerization process.

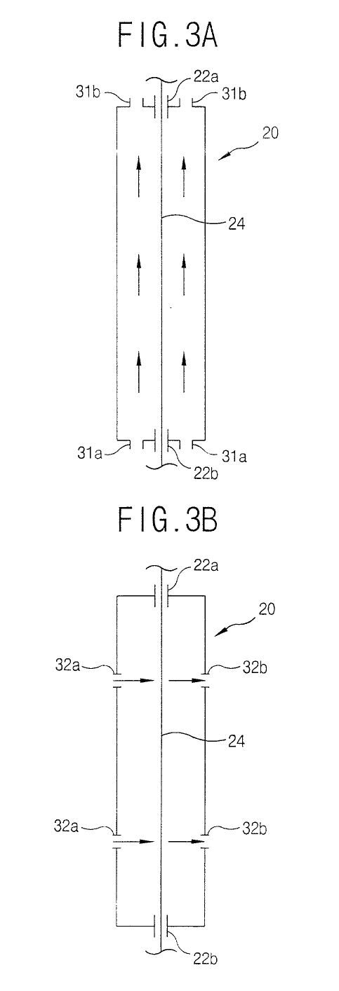

FIG. 4 is a sectional view of a horizontal chamber of a continuous processing apparatus by plasma polymerization in accordance with the preferred embodiment of the present invention.

Substance pass holes 45a and 45b are formed at right and left ends of the chamber, and an upper door 42a and a lower door 42b are installed at the upper and the lower portion of the chamber. Electrodes 43a and 43b are attached on the upper door and the lower door, respectively.

Though not shown, a gas inlet and a gas outlet may be formed at the chamber.

The electrode may be attached on the door face of the upper door and the lower door, or may be attached spaced apart from the door face.

The upper door is opened upwardly, while the lower door is opened downwardly.

The horizontal chamber may be used as a polymerization chamber, a pre-processing chamber or a post-processing chamber when the electrode is attached thereon. Or, without the electrode, the horizontal chamber may be simply used as a movement path for the substance.

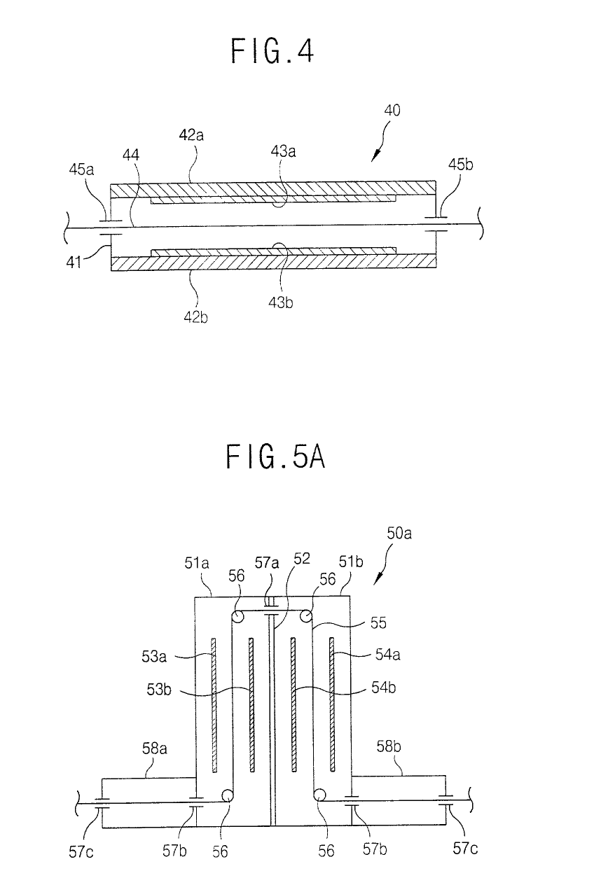

FIG. 5A is a sectional view showing a vertical chamber having two vertical areas in accordance with one embodiment of the present invention.

As shown in FIG. 5A, a vertical chamber 50a includes a partition plate 52 formed in the vertical direction at the center inside one chamber. The partition plate 52 divides the chamber into two vertical areas 51a and 51b. At least one electrode is disposed at each vertical area.

In the preferred embodiment of the present invention, two electrodes (53a and 53b, 54a and 54b) are formed facing to each other in each vertical area.

At the lower portion of the vertical chamber, horizontal paths (or a horizontal chamber) 58a and 58b are formed to be connected.

After substance 55 passes the left horizontal path 58a and is introduced into one horizontal area 51a, it passes the substance through hole 57a formed at the upper portion of the partition plate, is moved to another vertical area 51b, and then, passes another horizontal path 58b, so as to be moved out.

The movement of the substance may proceed in the opposite direction.

Since each vertical area of the vertical chamber is separated by the partition plate, it serves as an independent chamber and performs a surface processing with different processes, respectively.

For example, a pre-processing is performed at one vertical area and a polymerizing process is performed at the other vertical area. Or, after a polymerizing process is performed at one vertical area, a post-processing may be performed at the other vertical area.

Of course, polymerizing process may be performed at both vertical areas.

As for the integrated vertical chamber having two vertical areas, though the path of surface-processing of the substance is long, the area substantially occupied by the polymerization chamber is relatively small, and thus, it is very effective in view of space utilization. In addition, it is possible to perform two different surface processings for a substance being conveyed in a single chamber.

Reference numeral 57b denotes a substance pass hole between the vertical chamber and the horizontal path, 57c denotes a substance pass hole formed at the end of the horizontal path, and 56 denotes a tension roll.

FIG. 5B is a sectional view showing a vertical chamber having two vertical areas in accordance with another embodiment of the present invention.

As shown in FIG. 5B, the vertical chamber is the same as that of FIG. 5A in the aspect that the vertical chamber 50b is divided into two vertical areas by virtue of the partition plate 52 formed at the center inside the chamber, except that a substance 55, passing one vertical area 51a, passes another horizontal region 58 before proceeding to another vertical area 51b.

The horizontal area is integrally formed with the vertical chamber, and the substance is move between the vertical area and the horizontal path through the pass hole 57d formed between the vertical area and the horizontal area.

The vertical chamber having the integrally formed horizontal area and two vertical areas has advantages that since a surface processing is made independently at each area, space utilization is maximized, and the three kins of surface process can be consecutively performed in a single chamber.

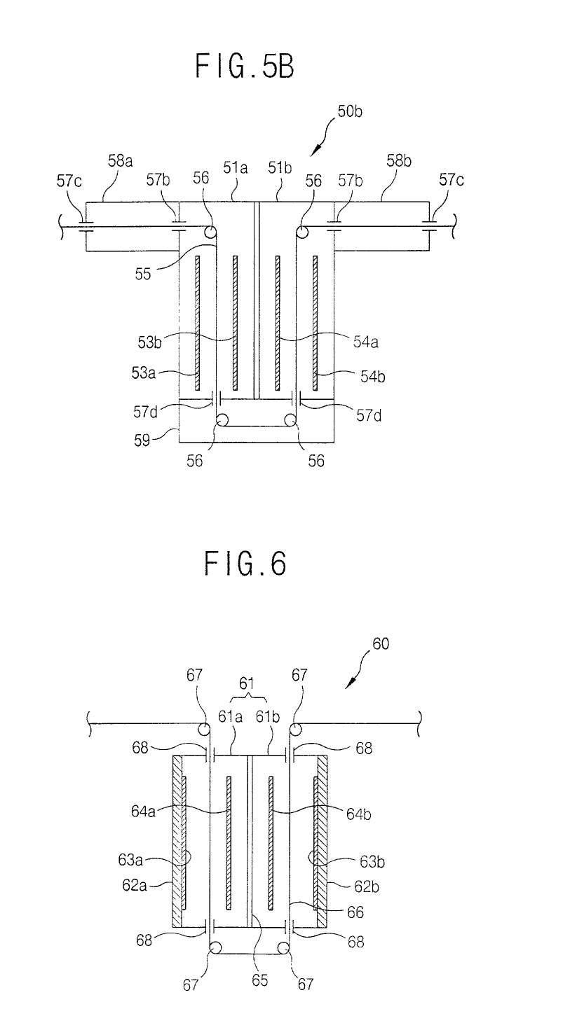

FIG. 6 is a sectional view showing a vertical chamber having two vertical areas in accordance with still another embodiment of the present invention.

As shown in FIG. 6, a vertical chamber 60 includes a chamber body 61 having two vertical areas 61a and 61b as divided by a partition plate 65 formed at the center inside the chamber, and chamber doors 62a and 62b installed at both ends of the chamber body, for opening and closing the chamber.

A substance 66 passes a through hole 68 and is moved in each vertical area of the vertical chamber. Each tension roll 67 changes a movement direction of the substance, rendering the substance to move from outside to the vertical area and from one vertical area to another vertical area.

The vertical chamber includes electrodes 64a and 64b disposed in parallel to the substance proceeding direction at both sides of the central partition plate 65 of the chamber body, and electrodes 63a and 63b are disposed in parallel to the substance proceeding direction on the door face of the chamber door.

The electrodes installed at the chamber door may be attached on the door face or disposed spaced apart from the door face so that the interval with the substance can be adjusted.

Though the substance moving from one vertical area to another vertical area is shown exposed outside space, it is preferred to connect an additional horizontal path (or a horizontal chamber) to the vertical chamber, similarly in the above embodiment.

As so far described, the continuous processing apparatus by plasma polymerization of the present invention has many advantages.

For example, first, since the vertical chamber can be possibly formed solely or by plural ones, or can be formed along with the horizontal chamber, various forms of plasma polymerization processing system can be constructed.

Secondly, the plurality of chambers can be utilized for various functions and use such as the polymerization chamber, the post-processing chamber and pre-processing chamber according to purposes of surface processing.

Thirdly, since the possibility that carbide generated as the electrode is carbonized falls down on the surface of the substance is considerably reduced, an ash removing unit for removing carbide or various ashes falling on the surface of the substance is not needed in the horizontal chamber.

Fourthly, since the gas injected into the chamber can flow upwardly and downwardly therein, gas can flow smoothly and evenly against both surfaces of the substance. Accordingly, even surface processing effect can be obtained on the both sides of the substance, and a reliability of the surface processing can be increased.

Fifthly, in case that some or all the chambers of the polymerization processing system are constructed as vertical chambers, since the installation space of the system can be remarkably reduced in a factory, it is favorable even in a space utilization.

Sixthly, since a tensile force is naturally applied when the substance passes the vertical chamber in the process that the substance to be surface-processed passes the chamber and conveyed, the substance is prevented from sagging down due to gravity.

The plasma polymerization processing apparatus including the vertical chamber is a requisite element for a continuous processing apparatus by which substances can be surface-processed rapidly and in large quantities.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the meets and bounds of the claims, or equivalence of such meets and bounds are therefore intended to be embraced by the appended claims.

What is claimed is:

1. A continuous processing apparatus by plasma polymerization having a plurality of chambers to perform a surface processing by plasma polymerization on the surface of a substance being moved into a chamber, comprises:
at least one vertical chamber in which a substance is vertically moved and at least one electrode is included therein.

2. The apparatus of claim 1, wherein the electrode is disposed in parallel to the movement direction of a substance in the chamber.

3. The apparatus of claim 2, wherein the chamber includes a plurality of electrodes, each being disposed in a line in parallel to the movement direction of a substance in the chamber.

4. The apparatus of claim 1, wherein the vertical chamber is a polymerization chamber in which the surface of a substance is processed by plasma polymerization.

5. The apparatus of claim 1, wherein the vertical chamber includes a substance pass hole formed at the upper and the lower sides.

6. The apparatus of claim 1, wherein the vertical chamber includes a substance pass hole at the top and the bottom thereof.

7. The apparatus of claim 1, wherein as power is applied to the substance, the substance itself is used as an electrode.

8. The apparatus of claim 1, wherein the vertical chamber comprises:
a chamber body in which a substance is moved vertically, one side thereof being opened,
a chamber door combined to the opened side of the chamber body; and
at least one electrode disposed in parallel to the movement direction of the substance.

9. The apparatus of claim 8, wherein the electrode is disposed in the chamber body.

10. The apparatus of claim 8, wherein the electrode is disposed at the chamber door.

11. The apparatus of claim 1, wherein the vertical chamber includes a partition plate at the center thereof, so that the vertical chamber is divided into two vertical areas by the partition plate.

12. The apparatus of claim 11, wherein the movement direction of a substance is the opposite to each other in the two vertical areas.

13. The apparatus of claim 11, wherein the two vertical areas includes at least one electrode disposed in parallel to the movement direction of the substance, respectively.

14. A continuous processing apparatus by plasma polymerization with a vertical chamber in which a plurality of chambers are provided to perform a surface processing by plasma polymerization on the surface of a substance being moved into a chamber, comprises:
a first vertical chamber in which a substance is moved vertically, having at least one electrode; and
a second vertical chamber in which a substance is moved vertically, having at least one electrode and being disposed spaced apart with a certain interval from the first vertical chamber.

15. The apparatus of claim 14, wherein at least one of the first and the second vertical chambers is a polymerization chamber in which a substance is surface-processed by plasma polymerization.

16. The apparatus of claim 15, wherein at least one horizontal chamber in which the substance is moved horizontally is included.

17. The apparatus of claim 16, wherein if the second vertical chamber is a polymerization chamber, one of the remaining chambers is a pre-processing chamber in which the surface of the substance is cleaned before being polymerized.

18. The apparatus of claim 16, wherein if the first ver5tical chamber is a polymerization chamber, one of the remaining chambers is a post-processing chamber in which air is injected thereinto and post-processing is performed by plasma discharging.

19. The apparatus of claim 16, wherein the horizontal chamber comprises:
a chamber body having a pass hole formed at the left and the right sides thereof so that the substance can pass therethrough;
an upper door having an electrode at the inner side thereof and being opened and closed upwardly; and
a lower door having an electrode at the inner side thereof and being opened and closed downwardly.

20. The apparatus of claim 15, wherein the first and the second vertical chambers are polymerization chamber having the same conditions at least one out of a kind of a gas supplied to the chamber, a supply rate of gases, a range of voltage applied to the electrode and the pressure inside the chamber.

21. A continuous processing apparatus by plasma polymerization with a vertical chamber including an unwinding chamber having an unwinding roll for unwinding a substance wound thereon, a winding chamber having a winding roll for winding a surface-processed substance, and a polymerization chamber in which the substance is surface-processed by plasma discharging after being conveyed from the unwinding chamber,
wherein the substance is vertically moved in the polymerization chamber and at least one electrode is included in the polymerization chamber.

22. The apparatus of claim 21, wherein the polymerization chamber comprises a chamber body having an electrode formed at the inner side thereof, and a door having an electrode formed at the inner side thereof and opening and closing the chamber body.

23. The apparatus of claim 21, wherein one of the chambers comprises:
at least one roller contacted by a substance being moved; and
a power supply unit for rendering the substance itself to become an electrode by contacting the roller as power is supplied to the roller.

24. A continuous processing apparatus by plasma polymerization with a vertical chamber, comprises:
an unwinding chamber having an unwinding roll for unwinding a wound substance;
a winding chamber having an winding roll for winding a surface-processed substance;
a first polymerization chamber for surface-processing the substance conveyed from the unwinding chamber by plasma discharging, and having substance pass hole formed at an upper and a lower sides and at least one electrode therein;
a second polymerization chamber for surface-processing the substance conveyed from the unwinding chamber by plasma discharging, and having substance pass hole formed at an upper and a lower sides and at least one electrode therein;
wherein the movement direction of the substance is opposite in the first and the second polymerization chamber

25. The apparatus of claim 24, wherein the first and the second polymerization chambers are an integrated chamber, respectively, in which a partition plate is formed at the center thereof to divide each chamber into two area.

26. The apparatus of claim 24, wherein the integrated chamber comprises:
a chamber body having a partition plate at the center thereof and an electrode disposed at both sides of the partition, and being opened at the left and right side; and
a first and a second doors having an electrode at the inner side thereof, and opening and closing the left and the right side of the chamber body.

27. The apparatus of claim 26, wherein the first door and the second door include an electrode disposed in parallel to the movement direction of the substance.
